(19) United States
(12) Patent Application Publication
(10) Pub. No.: US 2025/0126982 A1
(43) Pub. Date: Apr. 17, 2025

(54) DISPLAY MODULE AND DISPLAY DEVICE

(71) Applicant: HKC CORPORATION LIMITED, Shenzhen (CN)

(72) Inventors: Jing LI, Shenzhen (CN); Lidan YE, Shenzhen (CN)

(21) Appl. No.: 18/895,987

(22) Filed: Sep. 25, 2024

(30) Foreign Application Priority Data
Oct. 12, 2023 (CN) 202311318045.9

(51) Int. Cl. H10K 59/122; H10K 59/35

(52) U.S. Cl. CPC H10K 59/122; H10K 59/352

(57) ABSTRACT

A display module includes a display sub-pixel, and the display sub-pixel includes an anode layer, a cathode layer, a light-emitting function layer. The light-emitting function layer is provided between the anode layer and the cathode layer; the pixel define layer is provided around the light-emitting function layer and an aperture region is formed for light emergence; the light-emitting function layer includes a hole injection layer, a hole transport layer, a light-emitting layer, an electron transport layer and an electron injection layer provided sequentially in a direction from the anode layer to the cathode layer. The light-emitting function layer is extended at least partially to a side surface of the pixel define layer.

### CROSS-REFERENCE TO RELATED APPLICATIONS

The present application claims priority to Chinese Patent Application No. 202311318045.9, filed Oct. 12, 2023, the entire disclosure of which is hereby incorporated herein by reference.

### TECHNICAL FIELD

The present application belongs to the field of display, and particularly relates to a display module and a display device.

### BACKGROUND

Organic Light-Emitting Diode (OLED) has the advantages of high contrast and fast response speed. However, the OLED has a low light-emitting efficiency. In order to make the light of OLED meet the use requirements, usually a large current is provided to the OLED, which leads to the high power consumption of OLED.

### SUMMARY

There is provided a display module and a display device, which can effectively reduce the power consumption of an organic light-emitting diode according to embodiments of the present disclosure. The technical solution is as below.

According to one aspect of the present application, there is provided a display module, the display module includes a display sub-pixel, the display sub-pixel comprising an anode layer, a cathode layer, a light-emitting function layer, and a pixel define layer;
the anode layer and the cathode layer are provided opposite to each other;
the light-emitting function layer is provided between the anode layer and the cathode layer;
the pixel define layer is provided around the light-emitting function layer and an aperture region is formed for light emergence;
the light-emitting function layer includes a hole injection layer, a hole transport layer, a light-emitting layer, an electron transport layer and an electron injection layer;
the hole injection layer, the hole transport layer, the light-emitting layer, the electron transport layer and the electron injection layer are provided sequentially in a direction from the anode layer to the cathode layer,
the light-emitting function layer is extended at least partially to a side surface of the pixel define layer; and
the display sub-pixel further includes:
a hole catching layer provided between the pixel define layer and the hole injection layer, for gathering holes to the side surface of the pixel define layer and injecting holes into a corresponding light-emitting layer.

According to a second aspect of embodiments of the present disclosure, there is provided a display device, which includes a substrate, a thin film transistor layer and a display module as mentioned above, and the thin film transistor layer is provided on an upper surface of the substrate, and the display module is provided on an upper surface of the thin film transistor layer, and the thin film transistor layer includes a plurality of thin film transistors, and the anode layer of each display sub-pixel is connected to a source or a drain of each thin film transistor.

It should be understood in the present application that the above general description and the later detailed description are only exemplary and explanatory, and do not limit the present application.

### BRIEF DESCRIPTION OF THE DRAWINGS

The accompanying drawings herein are incorporated into and form a part of the specification, illustrate embodiments in accordance with the present application, and are used in conjunction with the specification to explain the principles of the present application. Obviously, the accompanying drawings in the following description are only some of the embodiments of the present application, and other accompanying drawings may be obtained from these drawings by those skilled in the art without any creative labour.

FIG. 1 is a structural view of a display module in a first embodiment of the present application.

FIG. 2 is a view showing locations of open and non-open regions in FIG. 1 of the present application.

FIG. 3 is a structural view of the hole catching layer in the green light display sub-pixel, the red light display sub-pixel, and the blue light display sub-pixel in the present application.

FIG. 4 is another structural view of the hole catching layer in the green light display sub-pixel, the red light display sub-pixel, and the blue light display sub-pixel in the present application.

FIG. 5 is a structural view of a pixel define layer of the display module in the present application.

FIG. 6 is a structural view of a display device in a second embodiment of the present application.

### DETAILED DESCRIPTION OF THE EMBODIMENTS

Embodiments will now be described more fully with reference to the accompanying drawings. However, the embodiments can be implemented in a variety of forms and should not be construed as limitation to the examples set forth herein; rather, the provision of these embodiments allows the present application to be more comprehensive and complete, and conveys the idea of the embodiments in a comprehensive manner to those skilled in the art.

### First Embodiment

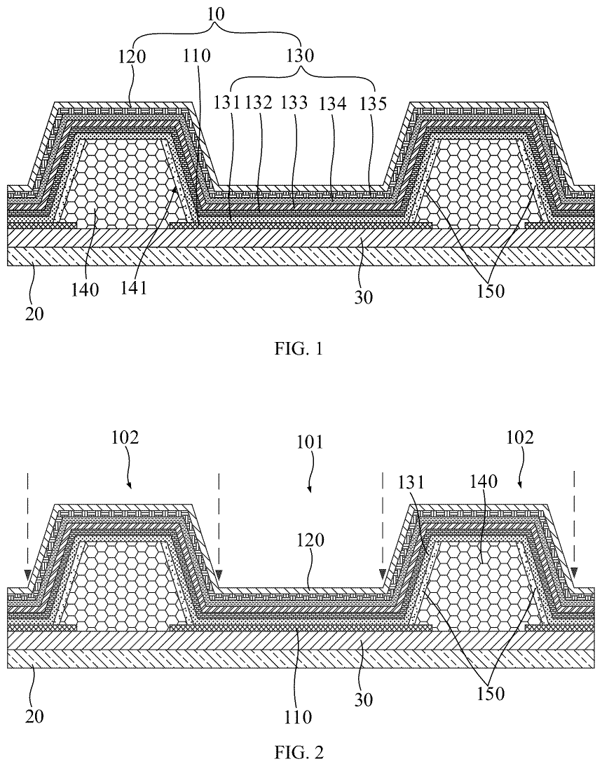

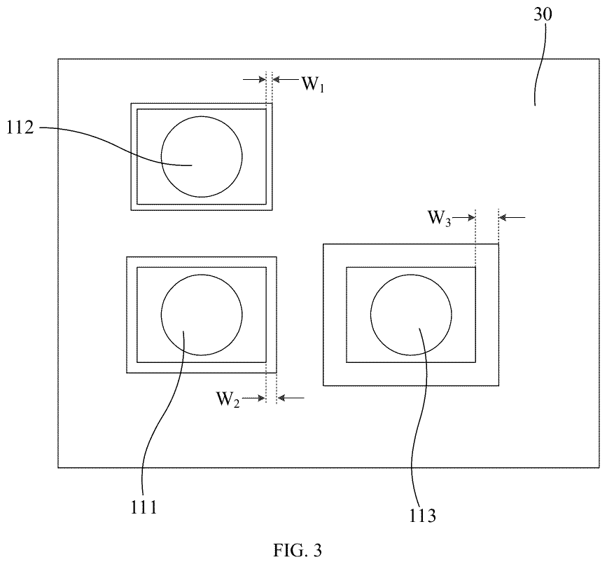

Referring to FIGS. 1 and 2, a display module is shown. The display module includes a display sub-pixel 10. The display sub-pixel 10 includes an anode layer 110 and a cathode layer 120. The anode layer 110 and the cathode layer 120 are provided opposite to each other, and the display sub-pixel 10 further includes a light-emitting function layer 130. In the present embodiment, the light-emitting function layer 130 is an OLED. The light-emitting function layer 130 is provided between the anode layer 110 and the cathode layer 120. When the light-emitting function layer 130 is lighted up, a current is provided to the anode layer 110 and the cathode layer 120, respectively. The display sub-pixel 10 also includes a Pixel Define Layer (PDL) 140, which is formed by using plasma-enhanced chemical vapour deposition. Both the anode layer 110 and the cathode layer 120 are transparent conductive layers, such as an Indium Tin Oxide (ITO) conductive layer, which is transparent indium tin oxide, and can be set by vapour phase deposition. After the anode layer 110 is set, the pixel define layer 140 is set.

The pixel define layer 140 is provided around the light-emitting function layer 130 and an aperture region 101 is formed for light emergence. A boundary location of the display sub-pixel 10 is defined by the pixel define layer 140. The light emitted by the light-emitting function layer 130 is emitted from the aperture region 101. It can be understood that the pixel define layer 140 is provided corresponding to the non-aperture region 102. The light-emitting function layer 130 includes a hole injection layer 131, a hole transport layer 132, a light-emitting layer 133, an electron transport layer 134, and an electron injection layer 135.

The hole injection layer 131 serves to effectively complete hole injection, and can also make the surface of the anode layer flatter, thereby improving the light-emitting efficiency and service life of the light-emitting function layer 130.

The hole transport layer 132 has a high mobility and can reduce the interfacial energy barrier, and also has high heat resistance stability. A stable amorphous shaped structure is usually formed during the vapour deposition of the device. The hole transport layer 132 belongs to an aromatic amine fluorescent compound, such as, tri-aromatic amine compounds.

The light-emitting layer 133 usually includes various organic thin film electroluminescent materials with excellent properties, such as organic small molecule materials and polymer materials. The organic small molecule materials include organic dyes, pigments, metal complexes, conjugated molecules, conjugated oligomers, etc. The organic polymer materials include polyphenylacetylene, polythiophene class of organic conjugated polymers, etc. The performance and quality of these materials are directly related to the performance and life of the light-emitting function layer. The light-emitting layer 133 can basically be divided into two categories. The most common category is that the electroluminescent body itself has the nature of carrier transport, that is, the main luminescent body. The other category is a guest luminescent body, which is usually some strongly fluorescent organic dyes dispersed in the main luminescent body by co-evaporation, which receive energy from the excited main exciter, resulting in the production of different colors (blue, green, and red) by energy transfer.

The main function of the light-emitting layer 133 is that the electrons and the holes are injected and compounded to form an exciton, and the exciton destabilizes to release energy or the photon returns to the ground state. The light-emitting layer 133 has a high fluorescence or phosphorescence efficiency in the solid state, and a good thermal and chemical stability.

The electron transport layer 134 has good electron mobility and has the best hole blocking capability. The electron transport layer 134 has a high glass transfer temperature and thermal stability, which avoids generation of Joule heating of the component when it is driven and avoids shortening the life of the component, especially at high electric field strengths and high current densities. The electron transport layer 134 can transfer electrons and also has a good ability to block holes. The electron transport layer 134 is thermally evaporated or rotationally coated to form a homogeneous and non-microporous film. The electron transport layer 134 are all aromatic compounds with large conjugate planes, and most of them have a good ability to accept electrons, and can effectively transfer electrons under a certain forward bias.

The electron injection layer 135 can help electrons to complete the injection from the cathode layer 120, and can also prevent corrosion of the metal electrodes. The electron injection layer 135 is usually an alkali metal compound, such as lithium oxide, potassium silicate, etc.; or an alkali metal acetate; or an alkali metal fluoride, commonly LiF.

The hole injection layer 131, the hole transport layer 132, the light-emitting layer 133, the electron transport layer 134, and the electron injection layer 135 are provided sequentially in a direction from the anode layer 110 to the cathode layer 120. When the light-emitting function layer 130 is made to emit light, holes from the anode layer 110 are injected in the hole injection layer 131, and the holes are positive electricity. The holes move toward the hole transport layer 132 and enter the light-emitting layer 133. The cathode layer 120 generates electrons in the electron injection layer 135, the electrons are negative electricity. The electrons move toward the electron transport layer 134 and enter the light-emitting layer 133, and the holes and the electrons meet in the light-emitting layer 133 to generate energy and release photons, thereby making the light-emitting function layer 130 to emit light.

The light-emitting function layer 130 is extended at least partially to the side surface 141 of the pixel define layer 140. It is to be understood that the hole injection layer 131, the hole transport layer 132, the light-emitting layer 133, the electron transport layer 134, and the electron injection layer 135 are also extended to the surface of the pixel define layer 140, i.e., the hole injection layer 131, the hole transport layer 132, the light-emitting layer 133, the electron transport layer 134 and the electron injection layer 135 are extended simultaneously.

The display sub-pixel 10 further includes a hole catching layer 150 provided between the pixel define layer 140 and the hole injection layer 131, and the hole catching layer 150 is configured for gathering holes to the side surface of the pixel define layer 140 and inject them into a corresponding light-emitting layer 133, such that the light-emitting efficiency is improved by increasing the number of holes in the light-emitting layer 133. The hole catching layer 150 is mainly a material such as a hydroxyl-substituted polyimide.

In this embodiment, when the light-emitting function layer 130 is working, the anode layer 110 and the cathode layer 120 are respectively energized with a current, a potential difference is formed between the anode layer 110 and the cathode layer 120. Under the action of the electric field in the anode layer 110 and the cathode layer 120, the holes generated by the anode layer 110 and the electrons generated by the cathode 120 move. The holes of the hole injection layer 131 are injected into the hole transport layer 132, the electrons of the electron injection layer 135 are injected into the electron transport layer 134, and the holes and electrons are migrated to the light-emitting layer 133, thereby causing the light-emitting layer 133 to emit light and generate visible light. The hole catching layer 150 can capture the holes and gather more holes in the hole injection layer 131, such that more holes are migrated into the light-emitting layer 133, thereby making the light-emitting layer 133 to generate more light. Moreover, in order to ensure that more light generated by the light-emitting layer 133 can be irradiated to the aperture region 1011, the hole catching layer 150 is provided toward the aperture region 101, so that more holes gather in the hole injection layer 131 that faces the aperture region 101, thereby improving the light-emitting efficiency of the light-emitting layer 133 in the corresponding direction. As can be seen, the technical solution of the present application can improve the light-emitting efficiency, and can decrease the supplied current and reduce the power consumption while ensuring the same brightness of the organic light-emitting diode.

It is to be further explained that since the transmission rate of holes is much higher than the transmission rate of the electrons, thus there will be an excess of holes in the light-emitting function layer 130. The technical solution of the present application makes use of the excess holes by the hole catching layer 150. During this process, the cathode layer 120 also covers the side surface 141 of the pixel define layer 140. That is, the cathode layer 120 is extended from the aperture region 101 to the non-aperture region 102, and the cathode layer 120 provides electrons in the non-aperture region 102, which sequentially pass through the electron injection layer 135 and the electron transport layer 134 to enter the light-emitting layer 133. The hole catching layer 150 in the non-aperture region 102 gathers the holes and then sequentially transmits them into the hole injection layer 131, the hole transport layer 132, and the light-emitting layer 133. Thus, it can be understood that the technical solution of the present application makes use of the structure of the light-emitting function layer 130 in the non-aperture region 102 due to the provision of the hole catching layer 150, thereby generating light at more locations and improving the light-emitting efficiency.

For the specific location of the hole catching layer 150, the side surface 141 of the pixel define layer 140 faces the aperture region 101, and the hole catching layer 150 is provided on the side surface 141 of the pixel define layer 140. The side surface 141 of the pixel define layer 140 is an inclined surface after the pixel define layer 140 is set completely. The side surface 141 of the pixel define layer 140 is provided towards the aperture region 101. It is to be understood that the hole catching layer 150 uses the side surface 141 of the pixel define layer 140 as a support structure to improve the stability of the hole catching layer 150. It is to be understood that the hole catching layer 150 is provided towards the aperture region 101. The hole injection layer 131, the hole transport layer 132, the light-emitting layer 133, and the electron transport layer 134 corresponding to the hole catching layer 150 are also provided towards the aperture region 101. As a result, the hole injection layer 131, the hole transport layer 132, the light-emitting layer 133, the electron transport layer 134, and the electron injection layer 135, sequentially provided on the hole catching layer 150, are also more robust and stable. It is also noted that the hole injection layer 131, the hole transport layer 132, the light-emitting layer 133, the electron transport layer 134, and the electron injection layer 135 provided on the hole catching layer 150 are also provided towards the aperture region 101, which improves the stability of the light-emitting function layer 130 while ensuring that the light increased by the light-emitting layer 133 can be irradiated to the aperture region 101.

In order to further improve the light-emitting efficiency, at least four side surfaces 141 of the pixel define layer 140 are provided towards the aperture region 101. It is understood that the four sides of the light-emitting function layer 130 are enclosed by the pixel define layer 140. The two adjacent side surfaces 141 are provided at an included angle to each other, and each side surface 141 is provided with one hole catching layer 150, such that the hole catching layer 150 is provided all around the light-emitting function layer 130, and the light-emitting efficiency of the light-emitting function layer 130 can be improved in four directions simultaneously. Of course, the pixel define layer 140 may also be surrounded to form other polygonal structures, such as a pentagon or a hexagon, and there may be provided five or six corresponding hole catching layer 150.

There may be two ways to set up the hole catching layer 150 in the present application.

Referring to FIG. 3, a first way is that two adjacent hole catching layers 150 are connected to each other. It is to be understood that each hole catching layer 150 on the pixel define layer 140 is connected to each other to form a whole circle of hole catching layer 150 surrounding the light-emitting function layer 130, so that the light-emitting efficiency can be improved all around. The dead space of the light-emitting efficiency is reduced.

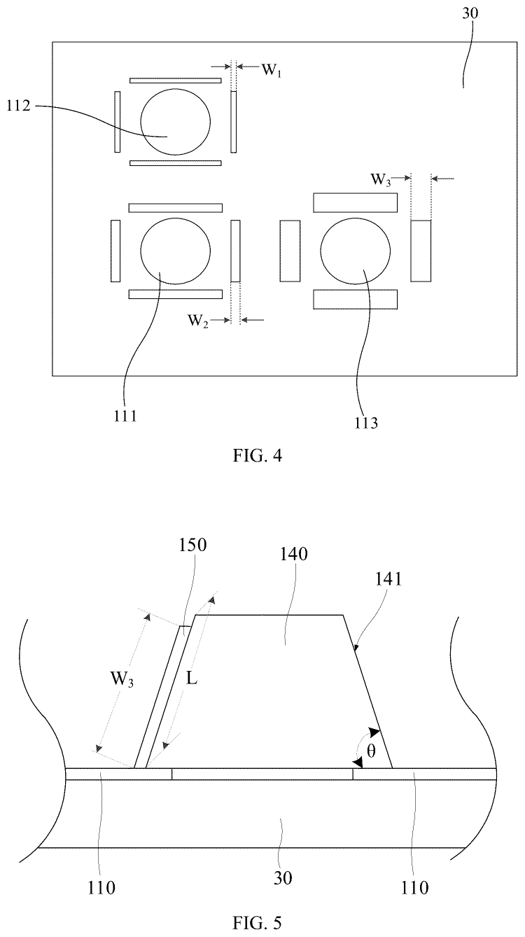

Referring to FIG. 4, a second way is that two adjacent hole catching layers 150 are spaced apart. For example, there are four hole catching layers 150, and the four hole catching layers 150 are spaced apart from each other and do not affect each other. Based on this, the hole catching layer 150 can be set up based on more specific targets. For the light-emitting function layer 130, if there exists a side with insufficient light-emitting efficiency, hole catching layers 150 with different laying areas can be set up to increase the area of the hole catching layer 150 on the side with insufficient light-emitting in a targeted manner, so that the whole light-emitting function layer 130 emits light more uniformly on its all around.

Referring to FIG. 5, in one aspect, an included angle θ is formed between the side surface 141 of the pixel define layer 140 and the anode layer 110, such that it is satisfied that the included angle θ is greater than 0° and less than 90°. For example, the included angle θ is 10°, 15°, 20°, 25°, 30°, 35°, 40°, 45°, 50°, 55°, 60°, 65°, 70°, 75°, or 80°. The included angle θ can also be any other value between 0° and 90°. Because the included angle θ is within the above range, it is ensured that the side surface 141 of the pixel define layer 140 is provided towards the aperture region 101.

In the present application, the display module includes a red light display sub-pixel 111, a green light display sub-pixel 112, and a blue light display sub-pixel 113, and the three colors of the OLEDs have different light-emitting efficiencies. In order to compensate for the brightness difference caused by the different light-emitting efficiencies, a width direction of the hole catching layer 150 is from an end of the hole catching layer 150 close to the light-emitting function layer 130 to an end of the hole catching layer 150 away from the light-emitting function layer 130. The green light display sub-pixel 112 has a width W₁ of the hole catching layer 150. The red light display sub-pixel 111 has a width W₂ of the hole catching layer 150, the blue light display sub-pixel 113 has a width W₃ of the hole catching layer 150, and it is satisfied that W₂ is greater than W₁ and less than W₃.

Referring again to FIGS. 3 and 4, the light-emitting efficiency of the green light display sub-pixel 112 is higher, the light-emitting efficiency of the red light display sub-pixel 111 is lower, and the light-emitting efficiency of the blue light display sub-pixel 113 is the lowest among the three. In order to balance the light-emitting efficiencies of the different color display sub-pixels 10, the width of the hole catching layer 150 of the blue light display sub-pixel 113 is increased to make W₃ larger, so that the hole catching layer 150 of the blue light display sub-pixel 113 can capture more holes, thereby increasing the number of blue light emitted from the blue light display sub-pixel 113. Accordingly, the width of the hole catching layer 150 of the green light display sub-pixel 112 is reduced to make W₁ smaller, so that the hole catching layer 150 of the green light display sub-pixel 112 can capture fewer holes, thereby reducing the number of green light emitted from the green light display sub-pixel 112. Further, the light-emitting efficiency of the red light display sub-pixel 111 is located between those of the green light display sub-pixel 112 and the blue light display sub-pixel 113, so that the width W₂ of the hole catching layer 150 of the red light display sub-pixel 111 is located between W₁ and W₃. The hole catching layer 150 of the blue light display sub-pixel 113 can spread over the entire side surface 141 of the pixel define layer 140, thereby making full use of the location of the side surface 141.

In addition, referring again to FIG. 5, the width of the side surface 141 of the pixel define layer 140 is defined as L, it is satisfied that a ratio of W₁ to L is greater than 0.3 and less than 0.8, a ratio of W₂ to L is greater than 0.3 and less than 0.8, and a ratio of W₃ to L is greater than 0.6 and less than 1.2. The dimensions of W₁ and W₂ are usually smaller than L. Thus, it can be understood that for the green light and the red light with higher light-emitting efficiency, the sizes of W₁ and W₂ are smaller, and the number of green and red light emitted can be well increased at this ratio. W₃ occupies a position that can exceed the size of L. W₃ can be then extended to the upper surface of the pixel define layer 140, further compensating for the lower light-emitting efficiency of the blue light.

In one aspect, a plurality of display sub-pixels 10 are sequentially arranged in a row-column direction, the cathode layers 120 between adjacent display sub-pixels 10 are connected, and the anode layers 110 of the adjacent display sub-pixels 10 are spaced apart. It can be understood that the cathode layer 120 may be provided as a whole layer, and the anode layers 110 are disconnected from each other. The corresponding display sub-pixels 10 are controlled to be lighted up or extinguished by controlling the anode layer 110 to be powered on or powered off.

Further, adjacent light-emitting function layers 130 may also be connected to each other, such as adjacent hole injection layer 131 are connected to each other, adjacent hole transport layer 132 are connected to each other, and adjacent light-emitting layers 133 are connected to each other. The adjacent electron transport layer 134 are connected to each other and the adjacent electron injection layers 135 are connected to each other, such that it is controlled to light up by energizing the corresponding position of the anode layer 110. In this, since the adjacent hole injection layers 131 are connected, a situation where the holes move towards the adjacent other display sub-pixels 10 occurs easily, and a problem of OLED flickering may occur. Based on this, the hole catching layer 150 in the present application can also block the movement of holes, and since the hole catching layer 150 is provided in the pixel define layer 140, i.e., between two adjacent light-emitting function layers 130, the holes will pass through the hole catching layer 150 when they move along the hole injection layer 131 to the adjacent light-emitting function layers 130, so that the hole catching layer 150 gathers the holes, thereby reducing the number of the holes transferring to the adjacent other light-emitting function layers 130, and the blocking of holes is completed.

As can be seen, the hole catching layer 150 in the present application can prevent other light-emitting function layer 130 from flickering abnormally while improving the light-emitting efficiency of the light-emitting function layer 130.

### Second Embodiment

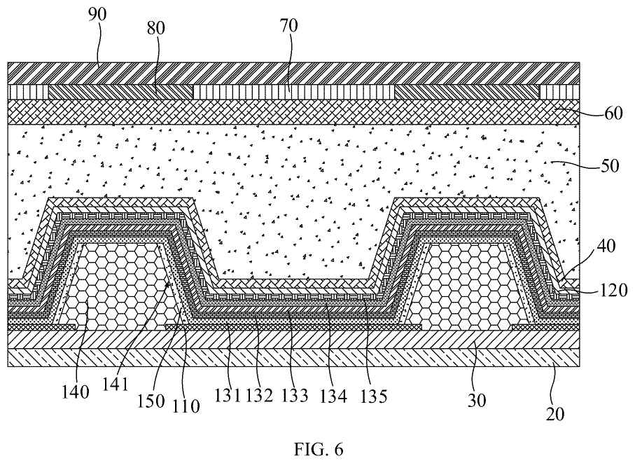

Referring to FIG. 6, the present application also provides a display device, the display device includes a substrate 20, a thin film transistor layer 30, and a display module. The thin film transistor layer 30 is provided on an upper surface of the substrate 20, and the substrate 20 mainly supports and protects an internal structure of the display device. The display module is provided on the upper surface of the thin film transistor layer 30. The thin film transistor layer 30 includes a plurality of thin film transistors (TFTs), and the anode layer 110 of each display sub-pixel 10 is connected to a source or a drain of the thin film transistor. The anode layer 110 may be connected to the source or the drain of the thin film transistor, and the anode layer 110 is supplied with power through the thin film transistor, so that the light-emitting function layer 130 is lighted up. The thin film transistor has advantages such as high responsiveness, and as a switch can well control the light-emitting function layer 130 to be lighted up or extinguished.

The display sub-pixel 10 further includes a color film layer 70 and a black matrix layer 80. The color film layer 70 is provided above the cathode layer 120 and covers the aperture region 101. The black matrix layer 80 is provided around the color film layer 70. A positive projection of the pixel define layer 140 on the substrate 20 is located within the positive projection of the black matrix layer 80 on the substrate 20. It is to be understood that the black matrix layer 80 is located in the non-aperture region 102. The aperture regions 101 of the different display sub-pixels 10 are provided with different color film layers 70 with different colors, for example, the aperture region 101 of the green light display sub-pixel 112 is covered with a green color film layer 70, the aperture region 101 of the red light display sub-pixel 111 is covered with a red color film layer 70, the aperture region 101 of the blue light display sub-pixel 113 is covered with a blue color film layer 70. These three color lights can be mixed in different proportions to form different display images.

Further, the display device of the present application further includes a first encapsulation layer 40, a second encapsulation layer 60, and a flat layer 50. The first encapsulation layer 40 is provided on the cathode layer 120, the flat layer 50 is provided on the first encapsulation layer 40, and the second encapsulation layer 60 is provided on the flat layer 50. The color film layer 70 and the black matrix layer 80 are provided on the second encapsulation layer 60. The first encapsulation layer 40 and the second encapsulation layer 60 are used to prevent water vapour from entering into the light-emitting function layer 130, and the flat layer 50 is used to make the surface of the entire display module flatter. The first encapsulation layer 40 and the second encapsulation layer 60 are inorganic materials, which can be set by way of chemical vapour deposition. The flat layer 50 is an organic material.

In addition, in order to improve the light-emitting efficiency, a reflection reduction layer 90 is provided above the color film layer 70 and the black matrix layer 80, and the reflection reduction layer 90 can reduce the reflection of light and increase the transmission of light, so that more light from the light-emitting function layer 130 is emitted.

Other embodiments of the present application will readily come to mind to those skilled in the art upon consideration of the specification and practice of the invention disclosed herein. The present application is intended to cover any variations, uses, or adaptations of the present application that follow the general principles of the present application and include common knowledge or customary technical means in the art not disclosed herein.

It is to be understood that the present application is not limited to the precise construction which has been described above and illustrated in the accompanying drawings, and that various modifications and changes may be made without departing from its scope. The scope of this application is limited only by the appending claims.

What is claimed is:

1. A display module, comprising a display sub-pixel, the display sub-pixel comprising an anode layer, a cathode layer, a light-emitting function layer, and a pixel define layer;
wherein the anode layer and the cathode layer are provided opposite to each other;
wherein the light-emitting function layer is provided between the anode layer and the cathode layer;
wherein the pixel define layer is provided around the light-emitting function layer and an aperture region is formed for light emergence;
wherein the light-emitting function layer comprises a hole injection layer, a hole transport layer, a light-emitting layer, an electron transport layer and an electron injection layer;
wherein the hole injection layer, the hole transport layer, the light-emitting layer, the electron transport layer and the electron injection layer are provided sequentially in a direction from the anode layer to the cathode layer;
wherein the light-emitting function layer is extended at least partially to a side surface of the pixel define layer; and
wherein the display sub-pixel further comprises:
a hole catching layer provided between the pixel define layer and the hole injection layer, for gathering holes to the side surface of the pixel define layer and injecting holes into a corresponding light-emitting layer.

2. The display module according to claim 1, wherein the side surface of the pixel define layer faces the aperture region, and the hole catching layer is provided on the side surface of the pixel define layer.

3. The display module according to claim 2, wherein at least four side surfaces of the pixel define layer are provided towards the aperture region, a side surface of the pixel define layer is angled with an adjacent side surface of the pixel define layer, and each side surface of the pixel define layer is provided with one hole catching layer correspondingly.

4. The display module according to claim 3, wherein two adjacent hole catching layers are connected to each other.

5. The display module according to claim 3, wherein two adjacent hole catching layers are spaced apart.

6. The display module according to claim 2, wherein when an included angle θ is formed between the side surface of the pixel define layer and the anode layer, and it is satisfied that the included angle θ is greater than 0° and less than 90°.

7. The display module according to claim 1, wherein a width direction of the hole catching layer is from an end of the hole catching layer close to the light-emitting function layer to an end of the hole catching layer away from the light-emitting function layer;
wherein the display module comprises a red light display sub-pixel, a green light display sub-pixel, and a blue light display sub-pixel;
wherein the green light display sub-pixel has a width W₁ of the hole catching layer;
wherein the red light display sub-pixel has a width W₂ of the hole catching layer;
wherein the blue light display sub-pixel has a width W₃ of the hole catching layer; and
wherein W₂ is greater than W₁ and less than W₃.

8. The display module according to claim 1, wherein a width direction of the hole catching layer is from an end of the hole catching layer close to the light-emitting function layer to an end of the hole catching layer away from the light-emitting function layer;
wherein the display module comprises a red light display sub-pixel, a green light display sub-pixel, and a blue light display sub-pixel;
wherein the green light display sub-pixel has a width W₁ of the hole catching layer;
wherein the red light display sub-pixel has a width W₂ of the hole catching layer;
wherein a width of the side surface of the pixel define layer is defined as L;
wherein a ratio of W₁ to L is greater than 0.3 and less than 0.8, a ratio of W₂ to L is greater than 0.3 and less than 0.8, and a ratio of W₃ to L is greater than 0.6 and less than 1.2.

9. The display module according to claim 1, wherein a plurality of display sub-pixels are sequentially provided in a row-column direction, cathode layers of adjacent display sub-pixels are connected, and anode layers of adjacent display sub-pixels are spaced apart.

10. A display device, comprising a substrate, a thin film transistor layer and a display module, wherein the thin film transistor layer is provided on an upper surface of the substrate, and the display module is provided on an upper surface of the thin film transistor layer;
wherein the display module comprises a display sub-pixel, the display sub-pixel comprising an anode layer, a cathode layer, a light-emitting function layer, and a pixel define layer;
wherein the thin film transistor layer comprises a plurality of thin film transistors, and the anode layer of each display sub-pixel is connected to a source or a drain of each thin film transistor;
wherein the anode layer and the cathode layer are provided opposite to each other;
wherein the light-emitting function layer is provided between the anode layer and the cathode layer;
wherein the pixel define layer is provided around the light-emitting function layer and an aperture region is formed for light emergence;
wherein the light-emitting function layer comprises a hole injection layer, a hole transport layer, a light-emitting layer, an electron transport layer and an electron injection layer;
wherein the hole injection layer, the hole transport layer, the light-emitting layer, the electron transport layer and the electron injection layer are provided sequentially in a direction from the anode layer to the cathode layer;
wherein the light-emitting function layer is extended at least partially to a side surface of the pixel define layer; and
wherein the display sub-pixel further comprises:
a hole catching layer provided between the pixel define layer and the hole injection layer, for gathering holes to the side surface of the pixel define layer and injecting holes into a corresponding light-emitting layer.

11. The display device according to claim 10, wherein the side surface of the pixel define layer faces the aperture region, and the hole catching layer is provided on the side surface of the pixel define layer.

12. The display device according to claim 11, wherein at least four side surfaces of the pixel define layer are provided towards the aperture region, a side surface of the pixel define layer is angled with an adjacent side surface of the pixel define layer, and each side surface of the pixel define layer is provided with one hole catching layer correspondingly.

13. The display device according to claim 12, wherein two adjacent hole catching layers are connected to each other.

14. The display device according to claim 12, wherein two adjacent hole catching layers are spaced apart.

15. The display device according to claim 11, wherein when an included angle θ is formed between the side surface of the pixel define layer and the anode layer, and it is satisfied that the included angle θ is greater than 0° and less than 90°.

16. The display device according to claim 10, wherein a width direction of the hole catching layer is from an end of the hole catching layer close to the light-emitting function layer to an end of the hole catching layer away from the light-emitting function layer;
wherein the display module comprises a red light display sub-pixel, a green light display sub-pixel, and a blue light display sub-pixel;
wherein the green light display sub-pixel has a width W₁ of the hole catching layer;
wherein the red light display sub-pixel has a width W₂ of the hole catching layer;
wherein the blue light display sub-pixel has a width W₃ of the hole catching layer; and
wherein W₂ is greater than W₁ and less than W₃.

17. The display device according to claim 10, wherein a width direction of the hole catching layer is from an end of the hole catching layer close to the light-emitting function layer to an end of the hole catching layer away from the light-emitting function layer;
wherein the display module comprises a red light display sub-pixel, a green light display sub-pixel, and a blue light display sub-pixel;
wherein the green light display sub-pixel has a width W₁ of the hole catching layer;
wherein the red light display sub-pixel has a width W₂ of the hole catching layer;
wherein a width of the side surface of the pixel define layer is defined as L;
wherein a ratio of W₁ to L is greater than 0.3 and less than 0.8, a ratio of W₂ to L is greater than 0.3 and less than 0.8, and a ratio of W₃ to L is greater than 0.6 and less than 1.2.

18. The display device according to claim 10, wherein a plurality of display sub-pixels are sequentially provided in a row-column direction, cathode layers of adjacent display sub-pixels are connected, and anode layers of adjacent display sub-pixels are spaced apart.
